(19) United States
(12) Patent Application Publication
(10) Pub. No.: US 2026/0213041 A1
(43) Pub. Date: Jul. 23, 2026

(54) Flexible Data Cable for Improving EMC Electromagnetic Compatibility and Preparation Method Thereof

(71) Applicant: Guangzhou Newlife Magnetics Co., Ltd., Guangzhou (CN)

(72) Inventors: Xiaoming Wang, Guangzhou (CN); Longzhang Wu, Guangzhou (CN); Chunsheng Guo, Guangzhou (CN); Zhiying Wang, Guangzhou (CN); Fucheng Liu, Guangzhou (CN)

(21) Appl. No.: 19/452,453

(22) Filed: Jan. 19, 2026

(30) Foreign Application Priority Data
Jan. 18, 2025 (CN) 202510079927.7

(51) Int. Cl. H01B 11/10; H01B 3/30; H01B 13/24; H05K 9/00

(52) U.S. Cl. CPC H01B 11/1083; H01B 3/30; H01B 13/24; H05K 9/0083; H05K 9/0098

(57) ABSTRACT

The present invention provides a flexible data cable for improving EMC electromagnetic compatibility including an inner flexible core, a middle flexible soft magnetic coating layer enclosing the inner flexible core, and an outer flexible protective layer enclosing the middle flexible soft magnetic layer, wherein the middle flexible soft magnetic layer is a composite material layer including a matrix having an additive and at least part sheet soft magnetic powder evenly distributed in the matrix, and at least part easy magnetization axis in the middle flexible soft magnetic coating layer has a circumferential surface orientation along an axial direction of the data cable. The orientation is established on the combination of axial direction+circumferential surface, and macroscopic morphology+microscopic easy magnetization axes, to improve the coverage rate and density of the axial circumferential surface, and the shielding effectiveness of the data cable in a 200 KHz-20 GHZ electromagnetic environment.

### CROSS-REFERENCE TO RELATED APPLICATION

The present application claims priority to Chinese patent application number CN 202510079927.7 filed Jan. 18, 2025, the entire contents of which are hereby incorporated by reference.

### FIELD OF THE INVENTION

The present invention generally relates to flexible soft magnetic wire, and more particularly, relates to a flexible data cable for improving EMC electromagnetic compatibility and preparation method thereof.

### BACKGROUND OF THE INVENTION

In the prior art, the electric field shielding of a data cable can be realized by single grounding mode of a metal woven layer or a metal foil layer. Reduction of electromagnetic field interference can be realized by means of twisted pair mode, soft magnetic ferrite magnetic ring, soft magnetic coating, and winding of a film coated with soft magnetic. Each mean has its own advantages in mechanical strength, service life, flexibility, production efficiency, permeability at different frequencies, and compatibility effectiveness of the data cable.

In the prior art, it is very difficult to improve the shielding effectiveness of non-static magnetic field and high frequency magnetic field. Theoretical studies show that the high frequency magnetic properties of soft magnetic microparticles used in the soft magnetic composites which are currently in large-scale production and widely used all follow the Snoek limit represented by the formula (1) as following:

$$( {μ}_{i} - 1 ) {f}_{r} = \frac{2}{3} {γ}^{′} {M}_{s} \qquad ( 1 )$$

wherein μᵢ is initial permeability, fr is natural resonance frequency (or cutoff frequency), y′ is gyromagnetic ratio, Ms is saturation induction density. Due to the limitation of Snoek limit, the operating frequency of current soft magnetic composites can only be below 100 kHz-200 kHz. As the electromagnetic frequency increases, the permeability decreases inversely, which hinders the application of soft magnetic composites in high-frequency microwave field. However, the frequency spectrum from radio frequency to microwave covers 3 kHz-300 GHz, and the EMC electromagnetic compatibility of electrical equipment in the electromagnetic environment becomes more and more difficult to satisfy as the magnetic field frequency increases, which poses a higher challenge to the data cable EMC electromagnetic compatibility, i.e. how to obtain ideal permeability and shielding effectiveness in 200 kHz-20 GHz electromagnetic environment in the electromagnetic field of the data cable.

If a sintering process is used, for a same sheet soft magnetic powder, the magnetic body has a high powder content, high density and high permeability. However, the rigidity of the sintered magnetic body will limit the flexibility of the wire. If a calendering process is used, the mechanical mode of rolling helps the sheet powder to be arranged neatly, so that the filling amount of the powder is increased, and the magnetic performance of the composite magnetic body is relatively improved. However, the calendering process cannot be directly used in wire forming. For extruded data calble, using sheet magnetic powder as modified filler, the higher the filling amount is, the easier the extruded wire intends to crack and, therefore, the improvement of the filling amount and density is limited. The improvement of the magnetic performance of the wire is also limited due to the need to take the mechanical strength and the flexibility of the data cable into account.

Chinese patent publication number CN118440435A relates to a polypropylene semi-conductive shielding material and preparation method and application thereof. CN118440435A discloses a polypropylene semi-conductive shielding material, based on the weight, the raw material includes 65-75 parts of polypropylene base material and elastomer base material, 20-30 parts of conductive carbon black, and 3-8 parts of functional assistant. The elastomer base material includes ethylene propylene terpolymer. The weight parts ratio of thepropylene base material to the elastomer is 1:(0.5-1). The functional assistant includes antioxidant, lubricant and dispersant. By regulating the carbon black to be evenly distributed in the polypropylene phase, the carbon black's permeation threshold is reduced, and the shielding material obtains balanced mechanical properties and surface smoothness, which can improve the tensile strength, elongation at break and electrical conductivity of the polypropylene semi-conductive shielding material, and effectively optimize thepropylene semi-conductive shielding. However, CN118440435A fails to involve any improvement of the EMC compatibility of electrical equipment under dynamic electromagnetic interference especially in high frequency electromagnetic environment.

Chinese patent publication number CN113674921A relates to a preparation method for a magnetic automatic curling freely stretchable data cable which physically guarantees the position and the means of magnetic absorption of the cable, so that the data cable can maintain a magnetic absorption normal state in a curled shape, thereby achieving smooth stretching action and reflecting a new trend in the magnetic absorption of cables. CN113674921A utilizes the surface magnetic field and magnetic adhesion force of permanent magnet materials, and fails to be related to the realization of EMC electromagnetic compatibility of the data cable in high-frequency electromagnetic environment and whether or not the magnetic permeability is enough.

### SUMMARY OF THE INVENTION

In view of the foregoing, one object of the present invention is to solve at least one of the following disadvantages in the prior art: in a high-frequency electromagnetic environment, the permeability complies with the Snoek limit. As the frequency increases, the permeability decreases reversely, and the electromagnetic shielding effectiveness of the data cable is challenged. During extrusion molding of the sheet magnetic powder, the higher the powder content is, the easier the wire intends to crack. Under the premise of meeting the mechanical strength such as the flexibility of the data cable, the powder content cannot be increased and improvement of the soft magnetic performance is limited.

According to one embodiment of the present invention, a flexible data cable for improving EMC electromagnetic compatibility includes an inner flexible core, a middle flexible soft magnetic coating layer enclosing the inner flexible core, and an outer flexible protective layer enclosing the middle flexible soft magnetic layer, wherein the middle flexible soft magnetic layer is a composite material layer including a matrix having an additive and at least part sheet soft magnetic powder evenly distributed in the matrix, and at least part easy magnetization axis in the middle flexible soft magnetic coating layer is circumferentially orientated along an axial direction of the data cable.

According to one aspect of the present invention, the easy magnetization axis of at least part individual crystals of the sheet soft magnetic powder is circumferentially oriented along an axial direction of the data cable, and hard magnetization axes thereof are partially reduced in volume.

According to one aspect of the present invention, at least part sheet soft magnetic powder has an axial circumferential effective area greater than a circumferential radial effective area thereof.

According to one aspect of the present invention, the effective area refers to the projected area.

According to one aspect of the present invention, at least part easy magnetization axis in the middle flexible soft magnetic layer has a circumferential orientation degree greater than a circumferential radial orientation degree thereof along the axial direction of the data cable.

According to one aspect of the present invention, sheet soft magnetic powder has a radius-thickness ratio greater than 1, preferably 25-200, further preferably 50-100.

According to one aspect of the present invention, the sheet soft magnetic powder has a median granularity D50 of 2-840 μm, preferably 2-160 μm, further preferably 47-84 μm.

According to one aspect of the present invention, the sheet soft magnetic powder has a weight specific surface area of 10-1590 m²/kg, preferably 40-300 m²/kg, and further preferably 86-159 m²/kg.

According to one aspect of the present invention, the shielding effectiveness of the data cable is no less than 20 dB at a frequency of 6.10G-17.24 GHz.

According to one aspect of the present invention, the outer flexible outer protective layer of the data cable is least one of an electrically insulating plastic layer, a woven layer, and a leather decoration layer.

According to one aspect of the present invention, the data cable has a diameter of 2.0-11.684 mm.

According to one aspect of the present invention, the data cable has a diameter of 2.0-5.0 mm, and the flexible soft magnetic coating layer has a thickness of 0.2-0.7 mm.

According to one aspect of the present invention, the soft magnetic powder is selected from Fe, carbonyl iron, Mn—Zn ferrite, Ni—Zn ferrite, an alloy formed by Fe and at least one of Co and Ni, FeSiAl, FeNiMo, R2(Fe,Ni,Si,Al)17N3, wherein R is Y, Ce, Nd, or Pr Sm2(Fe,Ni,Co)14B, and R2(Co,Fe,Ni)17, wherein R is Y or Nd.

According to one aspect of the present invention, the matrix is insulating molecular polymer.

According to one aspect of the present invention, the insulating molecular polymer includes at least one of thermoplastic resin, thermosetting resin, and synthetic rubber.

According to one aspect of the present invention, the data cable has a cross-section of axially symmetric regular shape comprising circular, flat, or ellipse, or has a cross-section of any irregular shape.

According to one aspect of the present invention, the data cable has a connector selected from USB type-c data connector, lightning data connector, and audio data connector.

According to one aspect of the present invention, a preparation method for flexible data cable for improving EMC electromagnetic compatibility includes the steps of:
step 1, preparing sheet soft magnetic powder;
step 2, granulating: mixing sheet soft magnetic powder, binder and additive in proportion, fully mixing and compounding, or modifying the sheet soft magnetic powder by a coupling agent, and mixing the modified the sheet soft magnetic powder, the binder and the additive and smelting, to obtain granular material of the middle flexible soft magnetic coating layer;
step 3, extrusion molding and sheet orientating: mixed plasticizing the granular material of step 2, and extruding the mixture of the inner flexible core and the mixed plasticized granular material via a same die of an extruder, to obtain a semi-finished product of the flexible data cable having the flexible core and the middle flexible soft magnetic coating layer enclosing the inner flexible core, during the extruding process, sheet soft magnetic powder in the viscous fluid binder adjusts stress surface under cooperation of shear force of inner sidewall of a charging barrel of the extruder and outer wall of the flexible core, viscous force of the binder and actuating pressure of a screw of the extruder, so that at least part of physical surface of sheet soft magnetic powder arranged along an axial circumferential surface to form a circumferential orientation along the axial direction of the data cable; and
step 4, forming the outer flexible outer protective layer: after cooling solidification, weaving electrically insulating outer flexible outer protective layer after the semi-finished product of the flexible data cable, or the outer flexible outer protective layer is electrically insulating plastic layer, which is extruded and formed synchronously or sequentially with step 3.

According to one aspect of the present invention, the preparation method of the sheet soft magnetic powder includes the steps of smelting, casting, crushing, ball milling, sieving, annealing, batch blending, raw powder, sheet-shaping, drying, heating treatment, wind selecting and batch blending, and obtaining finished product.

According to one aspect of the present invention, the flexible data cable is oriented and magnetized in a long straight spiral tube, a magnetic field direction in the spiral tube is parallel to an axial direction of the data cable, and an easy magnetization axis of at least part of the soft magnetic powder in the middle flexible soft magnetic coating layer is circumferentially oriented along an axial direction of the data cable.

According to one aspect of the present invention, temperature during the magnetizing orientation process is maintained at the viscoelastic temperature of the polymer.

According to one aspect of the present invention, the magnetizing orientation process is maintained until the polymer is cooled and solidified

According to one aspect of the present invention, the magnetic field is a magnetic field having at least 1.5 times the intrinsic coercive force Hcj of the soft magnetic powder, preferably greater than 3 times.

According to one aspect of the present invention, the magnetic field is a constant current field, or a pulsed magnetic field performed multiple times.

Compared with the prior art, the present invention at least has the following advantages:
1. Due to the axial circumferential orientation of sheet physical surface of the soft magnetic powder during extrusion molding, the axial circumferential orientation of the easy magnetization axis of the data cable after magnetization in the long straight spiral tube, the combination of axial/+circumferential orientation and the macro morphology and micro magnetization axis can increases the coverage and density of the axial circumferential of the data cable, thereby strengthening the contribution of the permeability. In the 200 KHz-20 GHZ electromagnetic environment, the shielding effectiveness of the data cable can be improved.
2. The temperature in the magnetizing orientation process is maintained to keep the viscous flow state of the polymer, and the soft magnetic composite layer is in the flow state, so as to reduce the coercive force and viscous force. In the constant or multiple pulse magnetic field parallel to the axial direction in the long straight spiral tube, more easy magnetization axes in the soft magnetic powder are oriented to maximize the circumferential orientation along the axial direction of the data cable, to improve the overall axial circumferential permeability of the data cable. After cooling consistency of the orientation of the mechanical orientation and the orientation direction of the easy magnetization axis is maintained. The use of the axial circumferential permeability is superimposed, which makes implement of large-scale and efficient production possible.
3. The shape and easy magnetization orientation of the sheet powder are axial circumferential, which enables the maximum utilization of the magnetic powder content according the ratio of the present invention, and the mechanical strength of the data cable after extrusion molding meets the overall flexibility requirements. No cracking occurs. The EMC electromagnetic compatibility of the data cable is improved. The structure and preparation method of the present invention are also applicable to other USB data cables, charging cables, audio cables, video cables, HDMI data cables, coaxial cables having a diameter of 5-11.684 mm etc.

### BRIEF DESCRIPTION OF THE DRAWINGS

In order to better illustrate the technical solution of the present invention, the present invention will be described in detail in view of the examples and the attached drawings. All the specific parameters and descriptions of the examples of the present invention are used for better illustration only, not for limitation of the present invention. Any replacement, recombination, deletion or addition that does not exceed the expected effect of the technical solution will fall within the scope of protection of the present invention.

FIG. 1 shows an illustrative view of magnetic field orientation structure of a data cable inside a long straight spiral tube; wherein 10 is flexible data cable, 20 is long straight spiral tube for magnetization, 30 is distribution of magnetic field lines;

FIG. 2 shows an illustrative structure of the flexible data cable; wherein 11 is flexible core, 12 is flexible soft magnetic coating layer, 13 is flexible outer protective layer; 10a is axial direction, 10b is circumferential direction, 10c is radial surface, 10d is circumferential surface;

FIG. 3-1 shows a SEM image of sheet FeSiAl 3H powder used for the flexible soft magnetic coating layer of the flexible cable in Example 1;

FIG. 3-2 shows a SEM image of sheet FeSiAl 1H powder used for the flexible soft magnetic coating layer of the flexible cable in Example 2;

FIG. 3-3 shows a SEM image of sheet FeSiAl 2H powder used for the flexible soft magnetic coating layer of the flexible cable in Example 3;

FIG. 3-4 shows a SEM image of non-sheet-like FeSiAl powder used for the flexible soft magnetic coating layer of the flexible cable in Comparative Example 1;

FIG. 4-1 shows a detection result of relationship between permeability and frequency of a ring-shaped sample of 3H powder having a powder content of 83.3% for Example 1;

FIG. 4-2 shows a detection result of relationship between permeability and frequency of a ring-shaped sample of 1H powder having a powder content of 83.3% for Example 2;

FIG. 4-3 shows a detection result of relationship between permeability and frequency of a ring-shaped sample of 2H powder having a powder content of 83.3% for Example 3;

FIG. 5-1 shows shielding effectiveness test results of 9 samples having powder content of 83.3% and widths of 1-9 cm of the composite material layer of the flexible soft magnetic coating layer of Example 1;

FIG. 5-2 shows shielding effectiveness test results of 9 samples having powder content of 83.3% and widths of 1-9 cm of the composite material layer of the flexible soft magnetic coating layer of Example 2;

FIG. 5-3 shows shielding effectiveness test results of 9 samples having powder content of 83.3% and widths of 1-9 cm of the composite material layer of the flexible soft magnetic coating layer of Example 3;

FIG. 5-4 shows shielding effectiveness test results of 4 samples having powder content of 83.3% and widths of 1-4 cm of the composite material layer of the flexible soft magnetic coating layer of Comparative Example 1;

FIG. 6-1 shows a top view of a shielding effectiveness test device and a sample to be tested; and

FIG. 6-2 shows an illustrative view of a shielding effectiveness test device, wherein 40 is test fixture and sample, 41 is microstrip line, 42a is signal input port, 42b is signal output port, 43 is sample to be tested, 50 is signal line, and 60 is vector analyzer.

Following is a further description of the embodiments of the present invention in combination with the accompanying drawings and examples, and the explanation is first to the description involved in the specification.

The temperature during the magnetization orientation process is adjusted according to the softening point of the adhesive actually used, and the heating time can be controlled by peripheral heating device, so that the matrix is in a viscous flow state.

The magnitude of the magnetic field is selected to meet the requirement of full saturation of the orientation and synchronous coordination of the orientation and cooling setting.

The direction of the magnetic field in the spiral tube is parallel to the axial direction of the data cable. Engineering error is allowed.

The easy magnetization axis refers to the fact that each magnetic powder contains at least one easy magnetization axis. During molding and magnetic field orientation process, easy magnetization axes as many as possible in each magnetic powder need to be oriented and maintained as required.

The thickness of the soft magnetic layer of the data cable is not an exact value. Uneven thickness during molding is allowed.

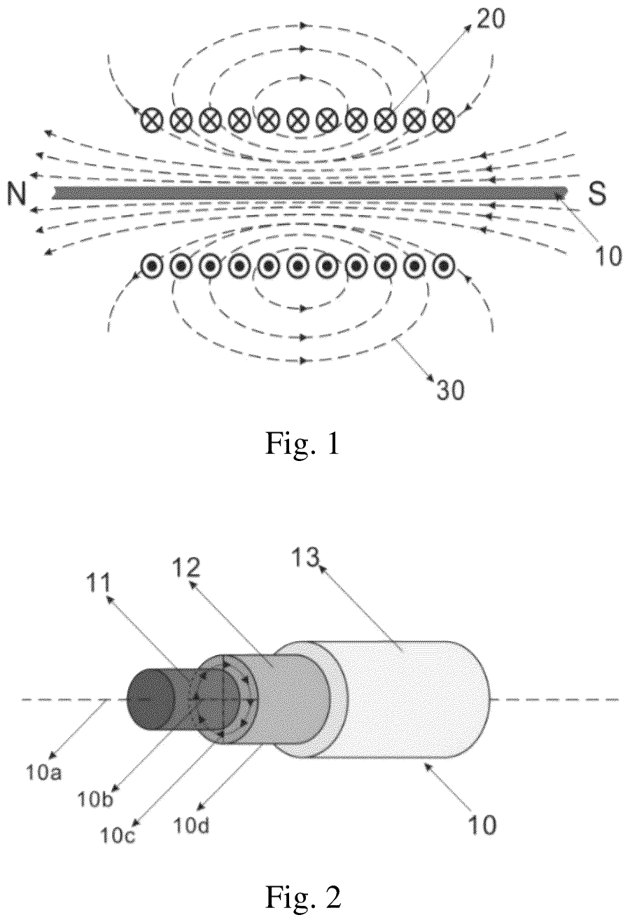

FIG. 1 shows orientation magnetization inside the long straight spiral tube 20: The spiral tube is a three-dimensional coil, which is a conductive wire that is singly or multiply wound. The winding is hollow inside. When the current I (A) is passed through the hollow spiral tube 20 with a total length of 1 (m) and a number of turns N, a magnetic field with a magnetic line distribution 30 is generated inside the hollow spiral tube 20. The magnitude of magnetic field can be adjusted. Suppose μ0 is the vacuum permeability, n is the number of turns of the coil per unit length, and the magnetic induction intensity of the finite straight solenoid is:

$$B = {μ}_{0} nI or B = {μ}_{0} \frac{N}{l} I \qquad ( 2 )$$

Referring to FIG. 2, axial direction 10a refers to a length direction of the central axis of the data cable, i.e. the direction of the long axis. Circumferential direction 10b refers to the direction of the tangent or arc at any point on the inner circumference of different radius with the center at any point on the long axis. Radial surface 10c refers to a cross section perpendicular to the axial direction of the data cable, with the center at any point on the long axis. Circumferential surface 10d refers to the collection of the axial side surfaces of a cylinder of different radius with the center at any point on the long axis of the data cable. The inner flexible core 11 includes a flexible single wire with single function, or a single wire or twisted pair wire with multiple functions such as flame retardant and insulation, such as at least one of power line, ground wire, signal line.

Soft magnetic refers to materials with low coercivity and high permeability.

EMC refers to “electromagnetic compatibility”, which means the ability of the electromagnetic energy generated by the data cable to neither interfere with other equipment nor be interfered by the electromagnetic energy of other equipment.

Referring to FIGS. 5-1, 5-2, 5-3, 5-4: Shielding effectiveness: In the absence of a shielding body, the field strength transmitted by a radiation interference source to a certain point (P) in the space is E1 (H1); After the shielding body is added, the field strength transmitted by the radiation interference source to the same point (P) in the space is E2 (H2). The shielding effectiveness is the ratio of the two field strengths, expressed in dB (decibels).

$$SE = 20 lg \frac{E 1}{E 2} ( dB ) \qquad ( 3 )$$

The detection method used in the present invention is the dual-port microstrip line method. The extrusion molding samples respectively made from sheet and non-sheet 1H powder, 2H powder and 3H powder having same content of 83.3% of the Examples and Comparative Examples each is placed on the microstrip line of the fixture, and tested under the same conditions at a frequency of 0.1 to 20 GHz. The shielding effectiveness and frequency relationship diagram under the same conditions are obtained through the vector network analyzer N5247A.

Referring to FIGS. 6-1 and 6-2, the dual-port microstrip line testing fixture has a characteristic impedance of 50Q, a port-to-port distance of 7 cm. The sample to be tested has a width ranging from 1 to 9 cm. The texture is verified to be excellent by a vector network analyzer calibrated by OSI T. For further information, please refer to the “Research on the Shielding Effectiveness Measurement of Carbonyl Iron Composite Material by dual-port microstrip Line Method” of Qiao Liang.

### DETAILED DESCRIPTION OF THE INVENTION

Referring to FIG. 2, a flexible data cable 10 for improving EMC electromagnetic compatibility includes an inner flexible core 11, a middle flexible soft magnetic coating layer 12 enclosing the inner flexible core 11, and an outer flexible protective layer 13 enclosing the middle flexible soft magnetic layer 12, wherein the middle flexible soft magnetic layer is a composite material layer comprising a matrix having an additive and at least part sheet soft magnetic powder evenly distributed in the matrix. The middle flexible soft magnetic coating layer 12 has a density of 2.53-2.95 g/cm³.

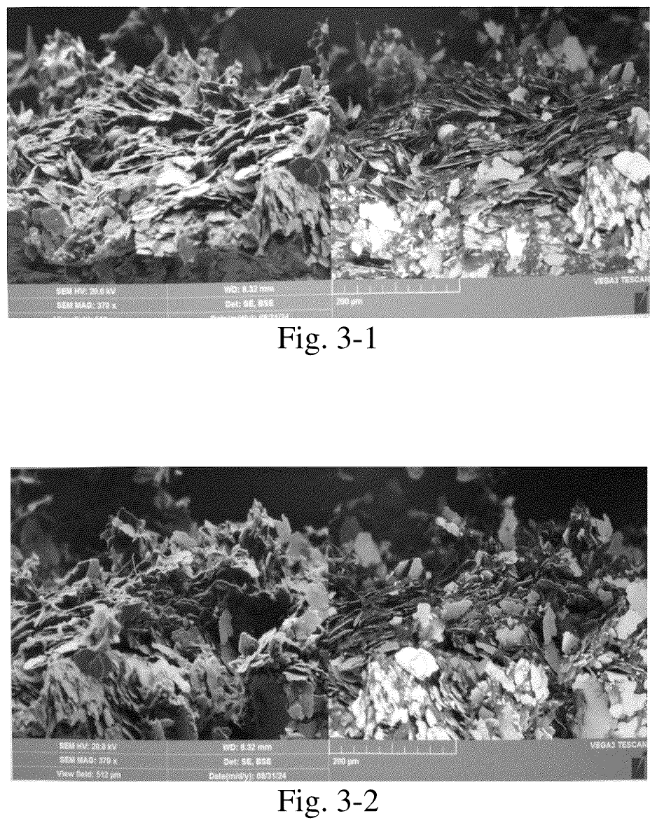

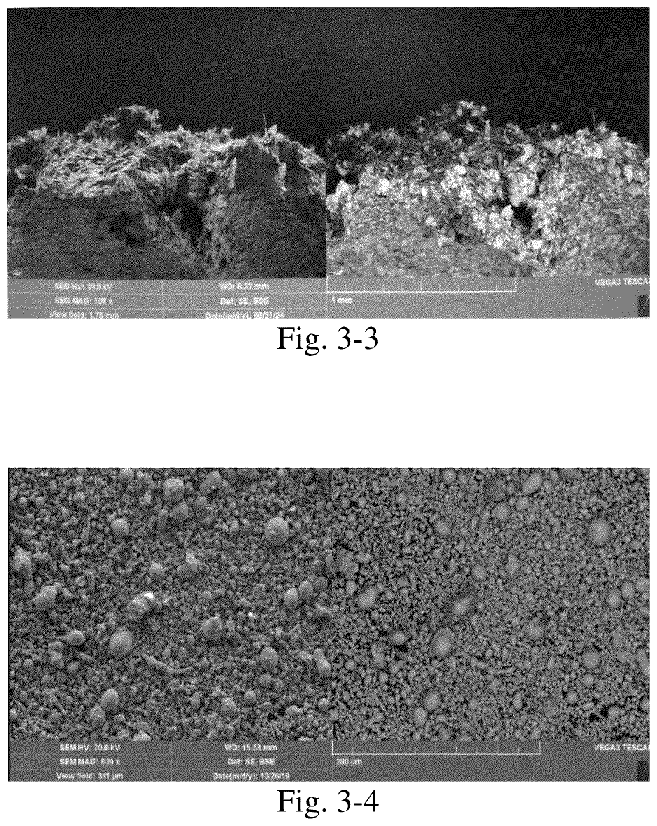

In Examples 1, 2, and 3, the sheet soft magnetic powder evenly distributed in the matrix having additive of the middle flexible soft magnetic coating layer is FeSiAl powder with a mass percentage of 9.4 silicon 5.6 aluminum, and the rest iron. The radius-thickness ratio of the sheet soft magnetic powder is 50 to 100, named as 3H powder, 1H powder and 2H powder respectively. The particle size distribution is recorded in Table 1, and the powder scanning electron microscope is shown in FIG. 3-1, FIG. 3-2, FIG. 3-3, respectively.

The preparation method of the sheet soft magnetic FeSiAl powder includes the steps of: smelting, casting, crushing, ball milling, sieving, annealing, batching, raw powder, sheet shaping, drying, heating treatment, wind selection, batching, and obtaining the finished product.

TABLE 1
Record of particle size distribution of sheet soft magnetic powder

| Example | 1 | 2 | 3 |
|---|---|---|---|
| Name of the sheet | 3H powder | 1H powder | 2H powder |
| powder | | | |
| D10(um) | 36.167 | 31.918 | 19.033 |
| D25(um) | 55.280 | 45.741 | 30.195 |
| D50(um) | 83.311 | 64.171 | 47.404 |
| D75(um) | 117.929 | 86.873 | 68.043 |
| D90(um) | 153.950 | 109.967 | 87.842 |
| D100(um) | 291.589 | 183.127 | 144.778 |
| D(3, 2)(um) | 66.373 | 54.346 | 36.047 |
| D(4, 3)(um) | 90.036 | 68.175 | 50.967 |
| Span | 1.414 | 1.216 | 1.452 |
| Weight specific surface | 86.094 | 105.146 | 158.522 |
| area (m2/kg) | | | |

Examples 1, 2, and 3 each has three different formulation, and the percentage content of at least part sheet FeSiAl soft magnetic powder evenly distributed in the matrix, binder, and additive in the middle flexible soft magnetic coating layer are recorded in Table 2, respectively. The corresponding hardness and density of the middle flexible soft magnetic coating layer of the extruded data cable are also recorded in Table 2 respectively.

Furthermore, the diameter of the extruded flexible data cable corresponding to each formulation is also given in three Examples. Each Example has 9 samples, and three Examples totally have 27 samples. The sample number and corresponding linear density are recorded in Table 2. The diameter in Table 2 includes the 5-core 60W inner flexible core, the middle flexible soft magnetic coating layer, and the linear density is the weight of a length of 1m.

TABLE 2
Parameter record of data cable and soft magnetic layer

| | name | powder | | | | | wire | | linear |
|---|---|---|---|---|---|---|---|---|---|
| | of the | content | binder | additive | hardness | density | diameter | sample | density |
| Example | powder | % | % | % | S-A | g/cm³ | mm | number | g/m |
| 1 | 3H | 83.3 | 15.8 | 0.9 | 54 | 2.91 | 3.50 | 1-1H | 29.5 |
| | powder | | | | | | 3.75 | 2-1H | 31.7 |
| | | | | | | | 4.00 | 3-1H | 36.2 |
| | | 80.3 | 18.9 | 0.8 | 51 | 2.68 | 3.50 | 4-1H | 28 |
| | | | | | | | 3.75 | 5-1H | 30.6 |
| | | | | | | | 4.00 | 6-1H | 33.6 |
| | | 78.1 | 21.1 | 0.8 | 50 | 2.55 | 3.50 | 7-1H | 24.6 |
| | | | | | | | 3.75 | 8-1H | 29.5 |
| | | | | | | | 4.00 | 9-1H | 31.9 |
| 2 | 1H | 83.3 | 15.8 | 0.9 | 54 | 2.95 | 3.50 | 1-2H | 27.7 |
| | powder | | | | | | 3.75 | 2-2H | 31.4 |
| | | | | | | | 4.00 | 3-2H | 37.6 |
| | | 80.3 | 18.9 | 0.8 | 52 | 2.71 | 3.50 | 4-2H | 26.4 |
| | | | | | | | 3.75 | 5-2H | 28.9 |
| | | | | | | | 4.00 | 6-2H | 35.4 |
| | | 78.1 | 21.1 | 0.8 | 50 | 2.55 | 3.50 | 7-2H | 23.7 |
| | | | | | | | 3.75 | 8-2H | 27.6 |
| | | | | | | | 4.00 | 9-2H | 31.4 |
| 3 | 2H | 83.3 | 15.8 | 0.9 | 54 | 2.87 | 3.50 | 1-3H | 27.6 |
| | powder | | | | | | 3.75 | 2-3H | 31.6 |
| | | | | | | | 4.00 | 3-3H | 37.1 |
| | | 80.3 | 18.9 | 0.8 | 51 | 2.73 | 3.50 | 4-3H | 25.5 |
| | | | | | | | 3.75 | 5-3H | 29.8 |
| | | | | | | | 4.00 | 6-3H | 35.3 |
| | | 78.1 | 21.1 | 0.8 | 50 | 2.53 | 3.50 | 7-3H | 24.2 |
| | | | | | | | 3.75 | 8-3H | 26.7 |
| | | | | | | | 4.00 | 9-3H | 31.2 |

The outer flexible protective layer of the 27 sample data cables in Table 2 is at least one of the plastic layer, woven layer, and leather decoration layer. The data cable has a circular cross section, and the total diameter is the sum of the diameter in the table and the diameter of the outer flexible protective layer, wherein one of the total diameter is 5 mm.

The binder of the middle flexible soft magnetic coating layer of the data cable of the 27 samples in Table 2 is TPE. The additive includes least one of lubricant, antioxidant, coupling agent, flame retardant, and dispersant. The diameter size of the data cable recorded in Table 2 is a middle flexible soft magnetic coating layer of 60 W including 5 cores, and therefore, the actual thickness of the middle flexible soft magnetic coating layer varies from 0.2 to 0.7 mm.

According to the relevant functions of the flexible core, the data cable of the 27 samples in Table 2 has a connector selected from USB type-c data connector, lightning data connector, and audio data connector.

A preparation method for flexible data cable for improving EMC electromagnetic compatibility of 27 samples in Example 1, 2 and 3, including the steps of:
step 1, preparing sheet soft magnetic iron-silicon-aluminum powder: taking weight percentage of 9.4 silicon, 5.6 aluminum and rest iron, for smelting, casting, crushing, ball-milling, sieving, annealing, batching, raw powder, sheet shaping, drying, heat treatment, wind selecting, batch blending, forming 3H, 1H and 2H sheet soft magnetic powder as recorded in Table 1;
step 2, mixing the sheet soft magnetic iron-silicon-aluminum powder with the components in Table 2 in proportion, fully mixing and compounding, to obtain the granular material A of the middle flexible soft magnetic coating layer;
step 3, mixed plasticizing the granular material of step 2, and extruding the mixture of the inner flexible core and the mixed plasticized granular material via a same die of an extruder, to obtain a semi-finished product of the flexible data cable having the flexible core and the middle flexible soft magnetic coating layer enclosing the inner flexible core, during the extruding process, sheet soft magnetic powder in the viscous fluid binder adjusts stress surface under cooperation of shear force of inner sidewall of a charging barrel of the extruder and outer wall of the flexible core, viscous force of the binder and actuating pressure of a screw of the extruder, so that at least part of physical surface of sheet soft magnetic powder arranged along an axial circumferential surface to form a circumferential orientation along the axial direction of the data cable; and
step 4, forming the outer flexible outer protective layer: after cooling solidification, weaving electrically insulating outer flexible outer protective layer after the semi-finished product of the flexible data cable after cooling solidification, or the outer flexible outer protective layer is electrically insulating plastic layer, which is extruded and formed synchronously or sequentially with step 3.

Referring to FIG. 1, in the 27 samples, the extruded semi-finished product 10 having flexible core and flexible soft magnetic coating layer, or the finished product 10 having flexible outer protective layer of the flexible data cable is oriented and magnetized in a long straight spiral tube 20. The inner magnetic field direction of the spiral tube is parallel to the axial direction of the data cable, the temperature in the magnetic orientation process is maintained at 180-220° C., the magnetic field strength is more than 3000 Oe-5000 Oe, and the easy magnetization axis of the magnetic powder in the flexible soft magnetic coating layer is circumferentially orientated along the axial direction of the data cable.

In the 27 samples, the middle flexible soft magnetic coating layer is a composite layer including a matrix having an additive and at least part sheet FeSiAl soft magnetic powder evenly distributed in the matrix, and at least part easy magnetization axis in the middle flexible soft magnetic coating layer is oriented circumferentially along the axial direction of the data cable. At least part physical surface of the sheet soft magnetic powder is oriented circumferentially along the axial direction of the data cable. At least part sheet soft magnetic powder has a circumferential effective area along the axial direction greater than the circumferential radial effective area. At least part easy magnetization axis along the axial direction of the data cable in the middle flexible soft magnetic coating layer has a circumferential orientation degree greater than the circumferential radial orientation degree. The middle flexible soft magnetic coating layer of the data cable in the 27 examples does not crack.

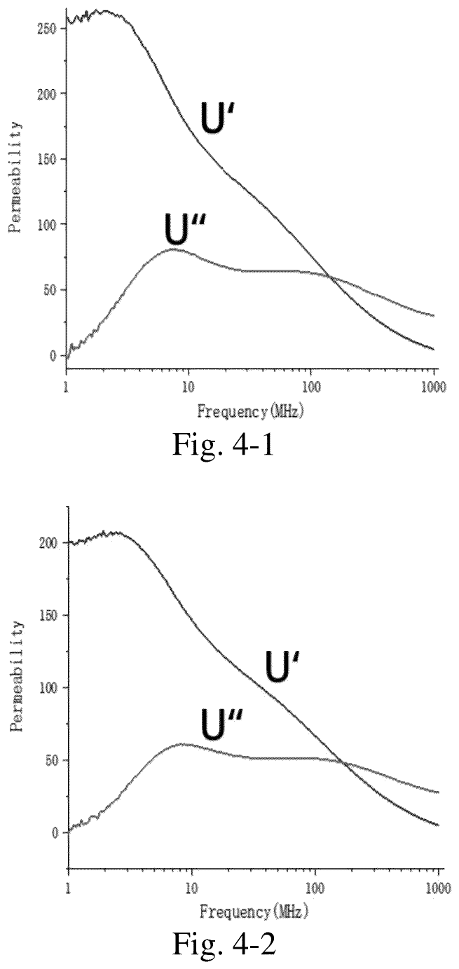

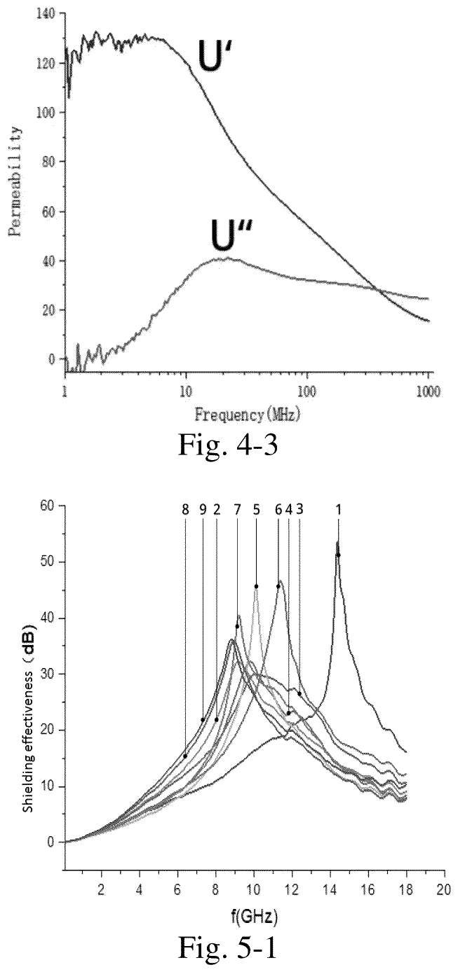

Comparative Example 1: Comparative Example 1 differs from Example 1 in that, the middle flexible soft magnetic coating layer of the data cable is a composite layer having non-sheet FeSiAl soft magnetic powder evenly distributed a matrix containing an additive. The SEM image of the non-sheet-like FeSiAl powder used for the flexible soft magnetic coating layer of the flexible cable is shown in FIG. 3-4. Comparative Example 1 has the same ratio of ingredient as Example 1 having 83.3% powder by weight in Table 2.

Comparative Example 2: Comparative Example 2 differs from Example 1 in that, the middle flexible soft magnetic coating layer of the data cable is a composite layer having 3H powder evenly distributed in the matrix containing an additive, with a powder content of 87.3% and a binder content of 11.8%. After molding, the middle flexible soft magnetic coating layer of the data cable cracks, and the data cable cannot be magnetized and oriented or covered with an outer flexible protective layer.

TABLE 3
Parameter record of data cable and soft magnetic layer of Comparative Examples

| | name of | powder | | | | | wire | | linear |
|---|---|---|---|---|---|---|---|---|---|
| Comparative | the | content | | additive | hardness | density | diameter | sample | density |
| Example | powder | % | binder % | % | S-A | g/cm3 | mm | number | g/m |
| 1 | non-sheet | 83.3 | 15.8 | 0.9 | 54 | 2.91 | 3.50 | 1-4 | 27.6 |
| | powder | | | | | | | | |
| 2 | 3Hpowder | 87.3 | 11.8 | 0.9 | none | none | none | none | none |

### A. Relationship Between Permeability and Frequency

Three examples each having a powder content of 83% corresponding to 3H powder, 1H powder and 2H powder respectively are selected, so as to detect permeability. Each sample has a ring shape and a thickness of 0.3 mm. Each sample has a size of Φ8.0×Φ3.04×0.3 mm. The samples are prepared via extrusion molding. Density and hardness of the samples are exactly the same as that of the flexible soft magnetic layer stripped from the data cable. The measurement results are shown in FIGS. 4-1, 4-2 and 4-3.

### Record and Analysis of Complex Permeability

As the frequency increases from 1 to 10 MHz, the real part of the permeability μ′ of examples 1, 2 and 3 remains at a high level of 120-250, and the imaginary part μ″ increases gradually. The real part u′ does not decrease unilater with the increase in frequency, but first increases and then decreases. When the frequency exceeds 100 MHz, the imaginary and real parts of examples 1 and 2 can still maintain above 50. The data cable according to the present application has broken through the limitation that the working frequency of the permeability of the flexible soft magnetic layer of the data cable in the prior art can only be within the range of 100 KHz-00 KHz. The three samples can still play the role of real and imaginary parts at 1000 MHz and above 1000 MHz, so as to meet the requirements of the permeability of the EMC electromagnetic compatibility in a dynamic electromagnetic environment.

### B. Measurement of Shielding Effectiveness of Data Cables

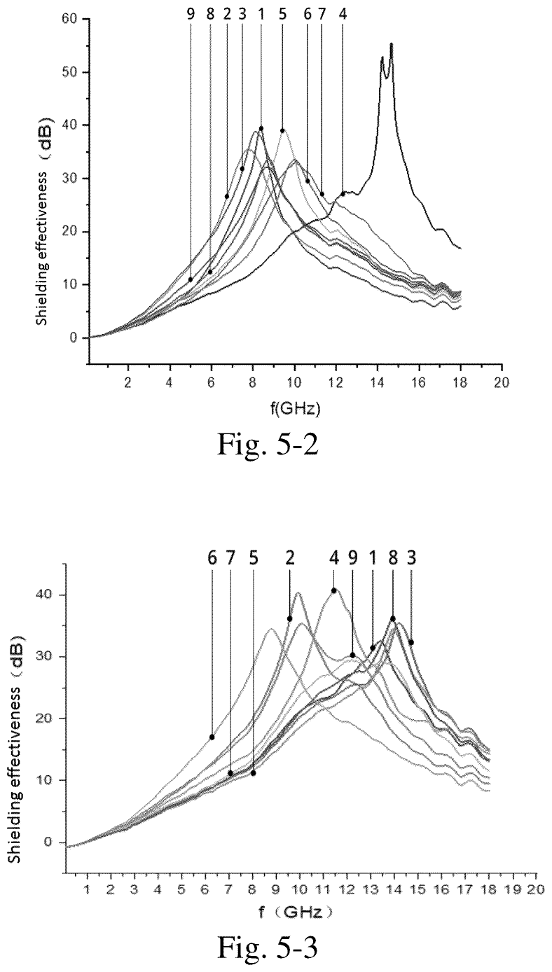

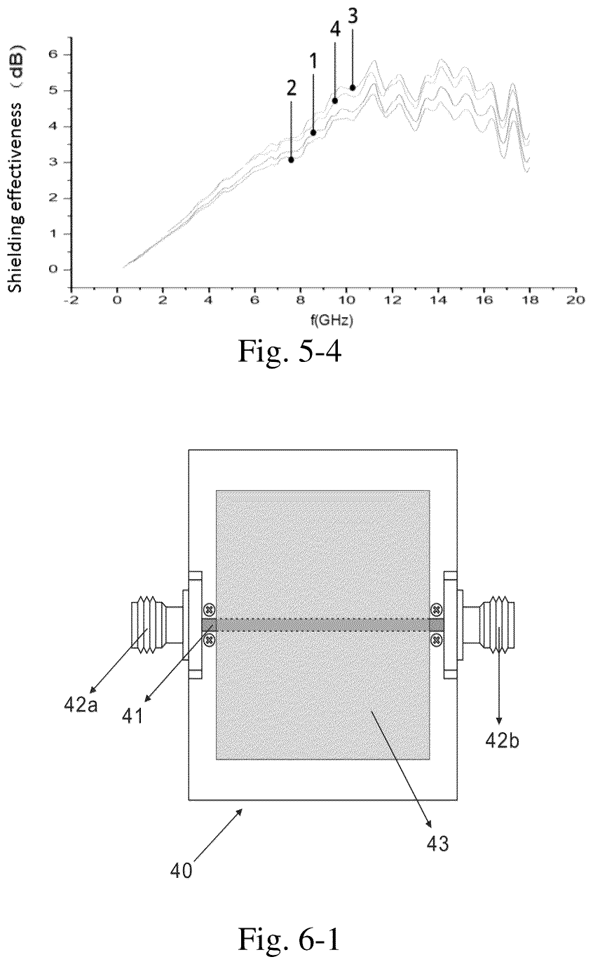

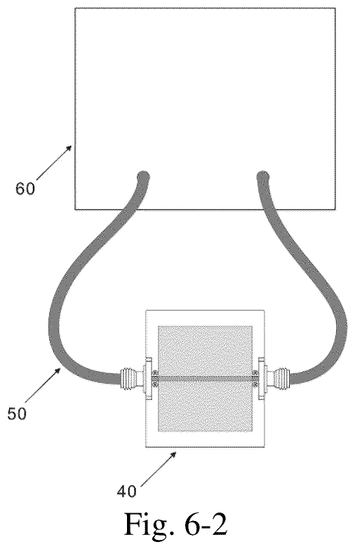

The soft magnetic composite layer of the data cables of the 27 samples in Table 2 were stripped off to form flexible sheets. Due to uneven thickness of the flexible sheets, direct detection cannot be carried out. During detection, the same extruded flexible composite that was stripped off was used for comparative detection. The detection samples each has same thickness of 0.4 mm, and a length of 7 cm as same as the length of the fixture. The detection samples have a same powder content of 83.3%, and have a width of 1 cm, 2 cm, 3 cm, 4 cm, 5 cm, 6 cm, 7 cm, 8 cm, and 9 cm, respectively. Examples 1, 2, and 3 each has 9 samples for the comparative detection. The samples were placed on a fixture shown in FIG. 6-1 of a shielding effectiveness test device shown in FIG. 6-2, and the comparative detection was performed at same condition using the dual-port microstrip line method at a frequency of 0.1-20 GHz. Using a vector network analyzer N5247A, 404 data points were taken on each sample to be detected. The shielding effectiveness results of the 9 samples of the three Examples were obtained respectively, as shown in FIGS. 5-1, 5-2, 5-3. The width of the sample to be detected of Comparative Example 1 was 1, 2, 3, and 4 cm respectively, and the shielding effectiveness detection results are shown in FIG. 5-4.

### Record and Analysis of Shielding Effectiveness

The 9 samples of Example 1, from 6.1G to 17.24 GHZ, all can achieve or exceed a shielding effectiveness of 20 dB. Samples 1, 6, 5, 7 have the best shielding effectiveness, the average value of 404 results measured from 0.1G to 18 GHz is 16.53 dB.

The 9 samples of Example 2, from 6.81G to 16.43 GHZ, all can achieve or exceed a shielding effectiveness of 20 dB. Samples 1, 4, 5 3 have the best shielding effectiveness, the average value of 404 results measured from 0.1G to 18 GHz is 16.27 dB.

The 9 samples of Example 3, from 7.13G to 17.15 GHZ, all can achieve or exceed a shielding effectiveness of 20 dB. Samples 4, 2, 6, 8 have the best shielding effectiveness, the average value from 0.1G to 18 GHz is 15.9 dB.

The 4 samples of the Comparative Example 1 have an average shielding effectiveness of 3.41 from 0.1G to 18 GHz, and the maximum shielding effectiveness value is no more than 6.

It can be seen that the shielding effectiveness of the data cable of the present invention has broken through the limitation that working frequency of the current soft magnetic composite material can only be below 100 KHz-200 KHz. The shielding effectiveness of the data cable of the present invention is much higher than the detection results of the 4 samples of the comparative example, so that the EMC electromagnetic compatibility of the data cable is improved.

The above described embodiments are only preferred embodiments of the present invention, and are not intended to limit the scope of the present invention. Any modification, equivalent replacement and improvement within the spirit and principle of the present invention should be included in the protection scope of the present invention.

What is claimed is:

1. A flexible data cable for improving EMC electromagnetic compatibility, comprising an inner flexible core, a middle flexible soft magnetic coating layer enclosing the inner flexible core, and an outer flexible protective layer enclosing the middle flexible soft magnetic layer, wherein the middle flexible soft magnetic layer is a composite material layer comprising a matrix having an additive and at least part sheet soft magnetic powder evenly distributed in the matrix, at least part easy magnetization axis in the middle flexible soft magnetic coating layer has circumferential surface orientation along an axial direction of the data cable, the at least part sheet soft magnetic powder has an axial circumferential surface effective area greater than a circumferential radial surface effective area thereof, and at least part easy magnetization axis in the middle flexible soft magnetic layer has a circumferential surface orientation degree greater than a circumferential radial surface orientation degree thereof along the axial direction of the data cable.

2. The flexible data cable for improving EMC electromagnetic compatibility of claim 1, wherein the sheet soft magnetic powder has a radius-thickness ratio of 25-200, and a median granularity D50 of 20-160 μm.

3. The flexible data cable for improving EMC electromagnetic compatibility of claim 1, wherein the outer flexible outer protective layer of the data cable is least one of an electrically insulating plastic layer, a woven layer, and a leather decoration layer.

4. The flexible data cable for improving EMC electromagnetic compatibility of claim 1, wherein the data cable has a wire diameter of 2.0-5.0 mm, and the middle flexible soft magnetic coating layer has a thickness of 0.2-0.7 mm and a density of 2.4-3.0/cm³.

5. The flexible data cable for improving EMC electromagnetic compatibility of claim 1, wherein the soft magnetic powder is selected from at least one of Fe, carbonyl iron, Mn—Zn ferrite, Ni—Zn ferrite, an alloy formed by Fe and at least one of Co and Ni, FeSiAl, FeNiMo, R2(Fe,Ni,Si,Al)17N3, wherein R is Y, Ce, Nd, or Pr, Sm2(Fe,Ni,Co) 14B, and R2(Co,Fe,Ni)17, wherein R is Y or Nd.

6. The flexible data cable for improving EMC electromagnetic compatibility of claim 1, wherein the matrix is electrically insulating high molecular polymer.

7. The flexible data cable for improving EMC electromagnetic compatibility of claim 1, wherein the data cable has a cross section of axially symmetric regular shape selected from anyone of circle, flat, or ellipse, or has a cross section of any irregular shape.

8. The flexible data cable for improving EMC electromagnetic compatibility of claim 1, wherein the data cable has a connector selected from USB type-c data connector, lightning data connector, and audio data connector.

9. A preparation method for flexible data cable for improving EMC electromagnetic compatibility of claim 1, comprising the steps of:
step 1, preparing sheet soft magnetic powder;
step 2, fully mixing sheet soft magnetic powder, binder and additive in proportion and compounding, or modifying the sheet soft magnetic powder by a coupling agent, and fully mixing the modified the sheet soft magnetic powder, the binder and the additive and smelting, to obtain granular material of the middle flexible soft magnetic coating layer;
step 3, mixing and plasticizing the granular material of step 2, and extruding a mixture of the inner flexible core and the mixed and plasticized granular material via a same die of an extruder, to obtain a semi-finished product of the flexible data cable having the flexible core and the middle flexible soft magnetic coating layer enclosing the inner flexible core, during extruding process, the sheet soft magnetic powder distributed in the viscous fluid binder adjusts stress surface under cooperation of shear force of inner sidewall of a charging barrel of the extruder and outer wall of the flexible core, viscous force of the binder and actuating pressure of a screw of the extruder, so that at least part physical surface of the sheet soft magnetic powder arranged along an axial circumferential surface to form a circumferential surface orientation along the axial direction of the data cable; and
step 4, weaving electrically insulating outer flexible outer protective layer after the semi-finished product of the flexible data cable after cooling solidification, or synchronously or sequentially extruding and forming the outer flexible outer protective layer with step 3 if the outer flexible outer protective layer is an electrically insulating plastic layer.

10. The preparation method of flexible data cable for improving EMC electromagnetic compatibility of claim 9, wherein preparation of the sheet soft magnetic powder comprises the steps of smelting, casting, crushing, ball milling, sieving, annealing, batch blending, raw powder, sheet shaping, drying, heating treatment, wind selecting, batch blending and obtaining a finished product.

11. The preparation method of flexible data cable for improving EMC electromagnetic compatibility of claim 9, wherein the flexible data cable is oriented and magnetized in a long straight spiral tube, a magnetic field direction in the spiral tube is parallel to an axial direction of the data cable, and an easy magnetization axis of at least part of the soft magnetic powder in the middle flexible soft magnetic coating layer has a circumferential surface orientation along an axial direction of the data cable.
